(19) United States
(12) Patent Application Publication
(10) Pub. No.: US 2026/0298980 A1
(43) Pub. Date: Oct. 1, 2026

(54) PROBE AND USE THEREOF

(71) Applicant: Prime Planet Energy & Solutions, Inc., Tokyo (JP)

(72) Inventors: Taku MATSUO, Kobe-shi (JP); Kanaru HASHISAKE, Kobe-shi (JP); Ryosuke IWATA, Kobe-shi (JP)

(21) Appl. No.: 19/571,487

(22) Filed: Mar. 19, 2026

(30) Foreign Application Priority Data
Mar. 28, 2025 (JP) 2025-054743

(51) Int. Cl. G01R 1/067; G01R 31/36

(52) U.S. Cl. CPC G01R 1/06722; G01R 31/3644

(57) ABSTRACT

A probe disclosed herein includes: an electrically conductive probe pin; a pressing member to press the probe pin against a test object; and a bearing portion holding the probe pin such that the probe pin is rotatable around an axis extending in a longitudinal direction of the probe pin. A front end of the probe pin includes: a flat contact portion that comes into direct contact with the test object; and a groove extending from a center of the front end toward its outer periphery.

### CROSS REFERENCE TO RELATED APPLICATIONS

The present application claims the benefit of priority to Japanese Patent Application No. 2025-054743 filed on Mar. 28, 2025. The entire contents of this application are hereby incorporated herein by reference.

### BACKGROUND

### Technical Field

The present disclosure relates to probes. The present disclosure also relates to probe units including the probes and to electricity storage device testing apparatuses. The present disclosure further relates to testing methods for testing electric characteristics of test objects using the probes and to electricity storage device manufacturing methods.

### Background Art

A probe is connected to a test object, such as an electricity storage device, and is used, for example, to supply or receive an electric current and an electric signal and measure an electric characteristic of the test object, such as an electricity storage device. To accurately supply, for example, an electric current and measure an electric characteristic, a favorable electric connection is preferably established between the probe and the object to which the probe is connected. JP 2013-61186A, for example, discloses a probe including a small-diameter conductive portion and a large-diameter conductive cylindrical portion disposed to surround the small-diameter conductive portion. The probe is configured such that a front end of the small-diameter conductive portion protrudes from a front end of the cylindrical portion and abuts against a target point preset on a test object. The probe further includes a spring portion that is located on a tubular wall surface of the large-diameter conductive cylindrical portion and to be compressed in a longitudinal direction. The probe is configured such that as the front end of the small-diameter conductive portion in abutment with the target point is pressed and moved backward, the spring portion rotates while being compressed, causing the front end of the small-diameter conductive portion to rotate. This enables removal of an oxide film present on the target point.

JP 2009-270836 A discloses a probe needle whose front end is brought into contact with an electrode of a measurement object so as to measure an electric characteristic of the measurement object. The front end of the probe needle has a substantially conical shape or substantially pyramidal shape. A top portion of the probe needle that comes into contact with the electrode is offset from an axis of the probe needle in a direction perpendicular to the axis. Thus, upon application of a load to the top portion after the contact of the probe needle with the electrode, the top portion slides and scratches an electrode surface. This enables removal of an oxide film from the electrode surface.

### SUMMARY

In recent years, there has been a need for electricity storage devices or other devices, which are test objects, to be higher in capacity or larger in size with increasing capacity. Such a large-size electricity storage device, for example, requires passage of an electric current, an electric signal, or other signal in large quantity when subjected to an evaluation test.

Techniques of the present disclosure provide probes, probe units, testing apparatuses, electricity storage device testing methods, and electricity storage device manufacturing methods, which will be described below. According to the techniques disclosed herein, unless any particular problem arises, one or more of constituent elements and processes mentioned herein may be omitted where appropriate, and any appropriate combination of the constituent elements and processes is possible.

### Item 1

A probe comprising: an electrically conductive probe pin; a pressing member to press the probe pin against a test object; and a bearing portion holding the probe pin such that the probe pin is rotatable around an axis extending in a longitudinal direction of the probe pin, wherein a front end of the probe pin includes a flat contact portion that comes into direct contact with the test object, and a groove extending from a center of the front end toward its outer periphery.

### Item 2

The probe according to item 1, wherein a contact area between the flat contact portion and the test object is at least 0.5 mm² or more, the front end of the probe pin includes flat contact surfaces defined by the groove, and the front end of the probe pin comes into contact with the test object through the contact surfaces.

### Item 3

The probe according to item 1 or 2, wherein a disengagement stopper to prevent disengagement of the probe pin is disposed adjacent to a rear end of the probe pin, a projection projecting along an outer circumference of the probe pin is disposed adjacent to the front end of the probe pin, the pressing member is disposed between the bearing portion and the projection, and the pressing member presses the probe pin against the test object with a repulsive force.

### Item 4

The probe according to any one of items 1 to 3, wherein the probe pin includes a current supply probe pin to supply an electric current, a voltage detection probe pin to detect a voltage, and an insulator insulating the current supply probe pin and the voltage detection probe pin from each other.

### Item 5

The probe according to item 4, wherein the current supply probe pin has a cylindrical shape, and the voltage detection probe pin is disposed inside the current supply probe pin, with the insulator interposed therebetween.

### Item 6

A probe unit to be connected to an electricity storage device, the probe unit comprising: a first probe to be connected to a first electrode; and
a second probe to be connected to a second electrode, wherein the first probe includes a first probe pin that is electrically conductive, a first probe pressing member to press the first probe against the first electrode, and a first probe bearing portion holding the first probe pin such that the first probe pin is rotatable around an axis extending in a longitudinal direction of the first probe pin, the second probe includes a second probe pin that is electrically conductive, a second probe pressing member to press the second probe against the second electrode, and a second probe bearing portion holding the second probe pin such that the second probe pin is rotatable around an axis extending in a longitudinal direction of the second probe pin, a front end of the first probe pin includes a flat contact portion that comes into direct contact with the first electrode, and a groove extending from a center of the front end of the first probe pin toward its outer periphery, and a front end of the second probe pin includes a flat contact portion that comes into direct contact with the second electrode, and a groove extending from a center of the front end of the second probe pin toward its outer periphery.

### Item 7

An electricity storage device testing apparatus comprising: the probe unit according to item 6; a holding plate to hold the electricity storage device and the probe unit; a current generation section to supply an electric current or electric signal to the electricity storage device through the first probe and/or the second probe; and a measurement section to measure an electric characteristic of the electricity storage device based on an electric signal received from the electricity storage device.

### Item 8

A testing method for testing an electric characteristic of a test object by bringing a front end of a probe into contact with the test object, the method comprising: a contact step of bringing the front end of the probe into contact with a terminal of the test object; a pressing and rotating step of rotating the front end of the probe while pressing the front end that is in contact with the terminal; a supplying step of supplying an electric current or electric signal to the test object; and a measuring step of measuring the electric characteristic of the test object based on an electric signal received from the test object.

### Item 9

The testing method according to item 8, wherein
the supplying step involves passage of a constant current of at least 20 A or more.

### Item 10

The testing method according to item 8 or 9, wherein
the testing object is an electricity storage device.

### Item 11

An electricity storage device manufacturing method comprising: a step of preparing an electricity storage device; a contact step of bringing a front end of a probe into contact with a terminal of the electricity storage device; a pressing and rotating step of rotating the front end of the probe while pressing the front end that is in contact with the terminal; a supplying step of supplying an electric current or electric signal to the electricity storage device; and a measuring step of measuring an electric characteristic of the electricity storage device based on an electric signal received from the electricity storage device.

According to the techniques of the present disclosure, the front end of the probe is rotated while being pressed against the test object, thereby enabling removal of an oxide film, a contaminant, or other substance present on a surface of the test object. Thus, the probe is able to maintain a favorable conduction with the test object. This allows passage of an electric current, electric signal, or other signal in large quantity when a test, such as an evaluation test, is conducted.

### BRIEF DESCRIPTION OF THE DRAWINGS

FIG. 1 is a schematic diagram of a probe.

FIG. 2 is a vertical cross-sectional view of the probe.

FIG. 3 is a plan view of a front end of the probe.

FIG. 4 is an enlarged view of the front end of the probe.

FIG. 5 is a perspective view of a lithium ion secondary battery.

FIG. 6 is an explanatory diagram illustrating a probe installation method for measurement of, for example, a voltage of the lithium ion secondary battery.

FIG. 7 is an explanatory diagram illustrating probe use conditions.

FIG. 8A is an explanatory diagram illustrating the probe and a test object in contact with each other.

FIG. 8B is an explanatory diagram illustrating the probe pressed against the test object.

FIG. 8C is an explanatory diagram illustrating how a film is removed upon rotation of the probe.

FIG. 9A is an explanatory diagram schematically illustrating a probe needle known in the art and a test object in contact with each other.

FIG. 9B is an explanatory diagram schematically illustrating the probe needle known in the art that is pressed against the test object.

FIG. 10 is a plan view of the front end of the probe provided with a cross-shaped groove.

FIG. 11 is a plan view of the front end of the probe provided with a linear groove.

FIG. 12 is a graph illustrating changes in terminal temperature during cycle test.

FIG. 13 is a graph illustrating changes in cell temperature in the lithium ion secondary battery during cycle test.

FIG. 14 is a graph illustrating changes in increase rate of cell resistance in the lithium ion secondary battery during cycle test.

### DETAILED DESCRIPTION

Preferred embodiments of probes according to the present disclosure will be described in detail below. Matters other than those specified herein but necessary to implement the present disclosure (e.g., a configuration, structure, or arrangement of an electricity storage device serving as an example of a test object) may be understood by those skilled in the art as design matters based on techniques known in this field. The present disclosure may be carried out based on what is described herein and common technical knowledge in this field.

### DEFINITION OF TERMS

In the drawings of this specification, components and elements similar in function are identified by common reference signs. Dimensions (e.g., lengths, widths, and thicknesses) depicted in the drawings do not reflect actual dimensions. The reference signs L, R, U, D, F, and Rr in the drawings respectively represent left, right, up, down, front, and rear. The reference sign X represents a right-left direction. The reference sign Y represents an up-down direction. The reference sign Z represents a front-rear direction. These directions, however, are defined merely for the sake of convenience of description and do not limit in any way how each probe or other device according to the present disclosure may be installed.

As used herein, any numerical range from “A” to “B” (where A and B are any numerical values) may be inclusive of A and B, may be greater than A and less than B, may be greater than A and less than or equal to B, and may be greater than or equal to A and less than B.

As used herein, the term “probe” refers to any device that supplies an electric current, electric signal, or other signal to a test object from an electric current source or other source (e.g., a power supply), or receives an electric current, electric signal, or other signal from the test object so as to transmit the received electric current, electric signal, or other signal to a measuring device or other device. Typical examples of such a probe include: a current probe that passes an electric current; a voltage probe that applies a voltage; and a special probe. Examples of the special probe include an optical probe, a logic probe, and an ultrasound probe. Each probe disclosed herein may be of any type, provided it does not significantly limit effects achieved by techniques of the present disclosure. Any suitable type of probe may be selected in accordance with a test object to be used and a purpose of a test to be performed (e.g., based on what kind of signal is to be received from a measurement object). Each probe disclosed herein may be passive or active. Each probe disclosed herein may be used to input or output, for example, an electric current.

### Probe 100

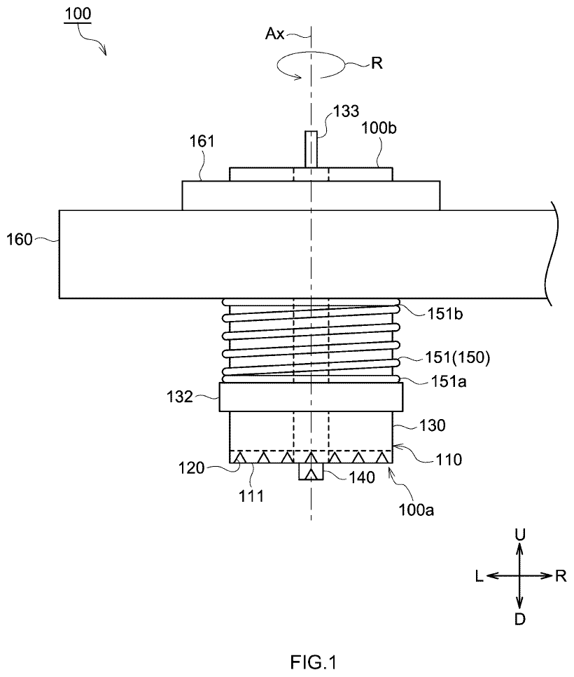

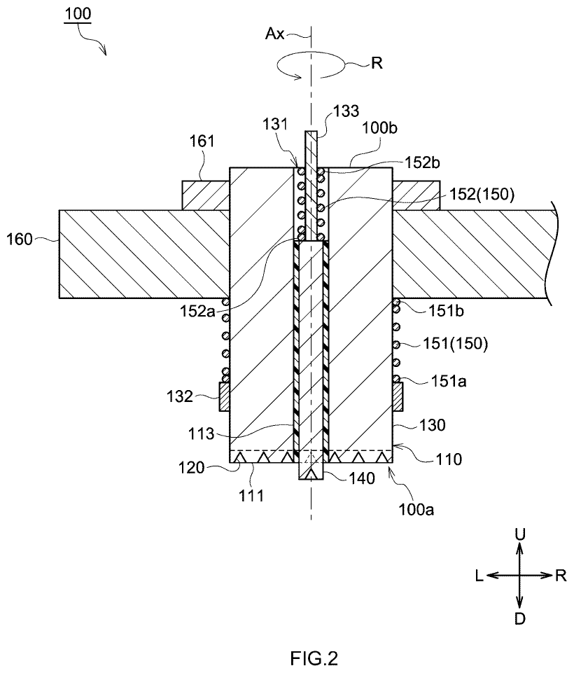

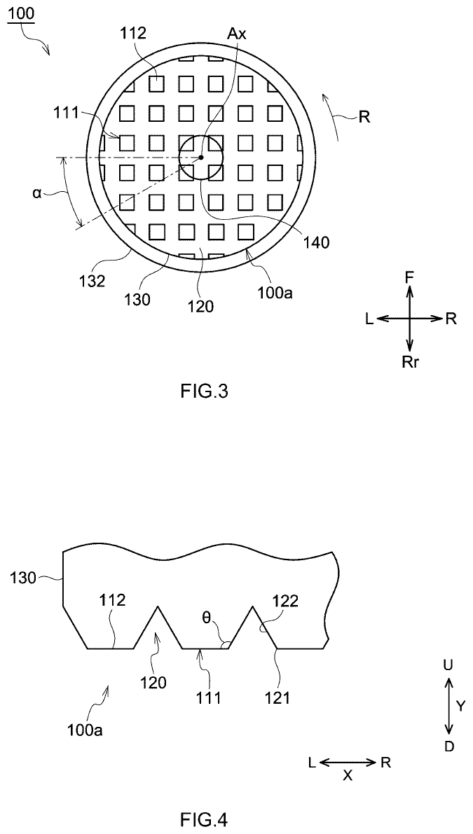

A preferred embodiment of the present disclosure will be described below with reference to the drawings. FIG. 1 is a schematic diagram of a probe 100. FIG. 2 is a vertical cross-sectional view of the probe 100. FIG. 3 is a plan view of a front end 100a of the probe 100. FIG. 3 presents a view from a side of the probe 100 that comes into contact with a test object for the sake of clarifying how a contact portion 111 of the probe 100 is structured. FIG. 4 is an enlarged view of the front end 100a of the probe 100. In the following description, a lithium ion secondary battery 1 is used as an example of the test object for the sake of convenience. As will be described below, the probe 100 in this embodiment is included in a probe unit 200 and brought into contact with a corresponding one of terminals (i.e., a positive terminal 35 and a negative terminal 45) of the lithium ion secondary battery 1 so as to measure an electric characteristic (e.g., a voltage) and calculate a resistance value between the probe 100 and the corresponding terminal.

The probe 100 includes a probe pin 110, a pressing member 150, and a bearing portion 160. The probe 100 disclosed herein is electrically connected to the test object by bringing the front end 100a of the probe 100 into contact with the test object. As illustrated in FIG. 1, the probe 100 in this embodiment further includes a disengagement stopper 161 and a projection 132. The bearing portion 160 serves as a base member with which the probe 100 is fixed in orientation. The probe pin 110 is supported by the bearing portion 160. The disengagement stopper 161 is attached adjacent to a rear end 100b of the probe 100 relative to the bearing portion 160, with the result that the probe pin 110 is supported in such a manner as to prevent its disengagement. The pressing member 150 is disposed between the bearing portion 160 and the projection 132. Fixing the bearing portion 160 allows the pressing member 150 to press the projection 132 toward the test object.

### Probe Pin 110

As illustrated in FIG. 1, the probe 100 includes the probe pin 110. The probe pin 110 is an electrically conductive rod member. In this embodiment, the probe pin 110 includes front and rear ends respectively corresponding to the front and rear ends 100a and 100b of the probe 100. A central axis Ax illustrated in FIG. 1 is a line passing through a center of the probe 100 and extending in a longitudinal direction of the probe 100 (which corresponds to the up-down direction Y in this embodiment).

In this embodiment, the probe pin 110 of the probe 100 includes more than one probe pin. As illustrated in FIG. 2, the probe pin 110 includes a current supply probe pin 130 and a voltage detection probe pin 140. The current supply probe pin 130 is able to receive or output an electric current of any magnitude from or to the test object. In other words, the current supply probe pin 130 serves as a current path for the test object. The voltage detection probe pin 140 is able to measure a voltage of the test object. In other words, the voltage detection probe pin 140 serves as a voltage path for the test object. In this embodiment, the current supply probe pin 130 is an outwardly located component of the probe pin 110. The voltage detection probe pin 140 is an inwardly located component of the probe pin 110. The current supply probe pin 130 has a cylindrical shape (i.e., a hollow shape). The current supply probe pin 130 includes a hollow portion 131 extending in the longitudinal direction (i.e., the up-down direction Y). The voltage detection probe pin 140 has a circular columnar shape (or is formed into a solid round bar). The voltage detection probe pin 140 is inserted into the hollow portion 131. The probe pin 110 is provided with an insulator 113 insulating the current supply probe pin 130 and the voltage detection probe pin 140 from each other. Specifically, the voltage detection probe pin 140 is disposed inside the current supply probe pin 130, with the insulator 113 interposed therebetween. This prevents direct electrical conduction between the current supply probe pin 130 and the voltage detection probe pin 140. Thus, the probe 100 is able to measure the voltage of the test object while passing an electric current to the test object. The probe pins, however, are not limited to this arrangement. In one example, a current supply probe pin may be placed inside a voltage detection probe pin. Alternatively, exactly one type of probe pin or three or more types of probe pins may be used.

As illustrated in FIG. 1, the probe pin 110 includes the front end 100a and the rear end 100b located opposite to the front end 100a. A current wire and/or a probe terminal, for example, are/is attached to the rear end 100b. In this embodiment, the rear end 100b is provided with an attachment portion 133. The attachment portion 133 extends from a rear end of the voltage detection probe pin 140. A voltage measurement terminal and/or a voltage wiring 261 are/is attached to the attachment portion 133. The front end 100a is brought into contact with the test object. In this embodiment, the front end 100a is brought into contact with the corresponding terminal (i.e., the positive terminal 35 or negative terminal 45) of the lithium ion secondary battery 1. As illustrated in FIG. 3, the front end 100a (i.e., an end of the probe pin 110) has a circular shape. Each probe pin, however, may have any other suitable shape. In one example, each probe pin may have an angular shape (such as a triangular shape, a pentagonal shape, or a hexagonal shape). The projection 132 is disposed adjacent to the front end 100a of the probe pin 110 so as to project along an outer circumference of the probe pin 110.

The front end 100a of the probe pin 110 includes the contact portion 111 and grooves 120. The contact portion 111 is a flat region that comes into direct contact with the test object. The grooves 120 are recesses extending from a center of the front end 100a toward its outer periphery. As illustrated in FIG. 3, this embodiment involves providing more than one groove 120 at the front end 100a of the probe pin 110. Thus, the probe pin 110 is provided with flat contact surfaces 112 defined by the grooves 120.

As illustrated in FIGS. 2 and 3, this embodiment involves inserting the circular columnar voltage detection probe pin 140 into the cylindrical current supply probe pin 130. A front end of the current supply probe pin 130 and a front end of the voltage detection probe pin 140 are each provided with the grooves 120 and the flat contact surfaces 112. In this embodiment, the current supply probe pin 130 is larger in area than the voltage detection probe pin 140 at the front end 100a of the probe pin 110 because a high electric current is passed through the current supply probe pin 130. This ensures a large contact area between the current supply probe pin 130 and the test object. The present disclosure, however, is not limited to this arrangement. The contact area between the current supply probe pin 130 and the test object may be equal to the contact area between the voltage detection probe pin 140 and the test object. A surface of contact between the voltage detection probe pin 140 and the test object may be larger than a surface of contact between the current supply probe pin 130 and the test object. The insulator 113 is provided so as to cover an outer periphery of the circular columnar voltage detection probe pin 140.

The probe 100 is required to include at least one type of probe pin. Each probe pin is not limited to any particular type or use. Where appropriate, each probe pin may be replaced with another type of probe pin depending on a purpose of measurement. In one example, the probe pin 110 may consist of the current supply probe pin 130. In another example, the probe pin 110 may include a voltage supply probe pin so as to be able to apply a voltage to the test object.

The contact portion 111 of the probe pin 110 disclosed herein is flat. Specifically, a portion of the probe pin 110 that comes into contact with the test object is flat. As illustrated in FIG. 4, the probe 100 in this embodiment is configured such that the flat contact portion 111 of the probe pin 110 is brought into contact with the corresponding terminal (i.e., the positive terminal 35 or negative terminal 45) of the lithium ion secondary battery 1. This contact brings the probe 100 into conduction with the lithium ion secondary battery 1, thus allowing, for example, a power source to supply an electric current, electric signal, or other signal to the test object through the contact portion 111. Because the contact portion 111 is flat, a large contact area is secured between the contact portion 111 and the test object. Depending on the test object, a high electric current needs to be passed. In such a case, a temperature rise occurs between the test object and the contact portion 111. From the viewpoint of reducing such a temperature rise, it is preferable to increase the contact area between the contact portion 111 and the test object. For a stationary conduction current, the contact area to be secured may be 0.1 mm²/A or more, preferably 0.5 mm²/A or more, and more preferably 0.7 mm²/A or more.

As illustrated in FIG. 4, the grooves 120 at the front end 100a include edges 121 and rake faces 122. The edges 121 are formed on junctions between the contact surfaces 112 and the grooves 120. The edges 121 shave off a film formed at an interface between the probe 100 and the test object. The rake faces 122 are side wall faces that define the grooves 120. The rake faces 122 scoop up the film, which is formed at the interface between the probe 100 and the test object, into the grooves 120 such that the film is squeezed into the grooves 120. From the viewpoint of increasing the edges 121 in strength, an inclination θ of the rake faces 122 with respect to the contact surfaces 112 is preferably an obtuse angle. In this embodiment, the grooves 120 extend continuously in straight lines from the center of the front end 100a toward its outer periphery. The grooves 120, however, are not limited to this arrangement. The grooves 120 may be formed in a non-continuous manner. When more than one groove 120 is formed, the grooves 120 may have any pitch within a range that does not significantly impair the effects achieved by the techniques of the present disclosure. To make the contact portion 111 flat, the pitch of the grooves 120 is preferably 0.1 mm or more, more preferably 0.3 mm or more, and most preferably 0.5 mm or more. The grooves 120 may have any depth within a range that does not significantly impair the effects achieved by the techniques of the present disclosure. The film, such as an oxide film or contaminant (e.g., flux), formed at the interface between the probe 100 and the test object, may be a thin film with a thickness of, for example, about 1 μm. Accordingly, the grooves 120 preferably have a depth of about 1 μm or more. The grooves 120 may have any suitable width.

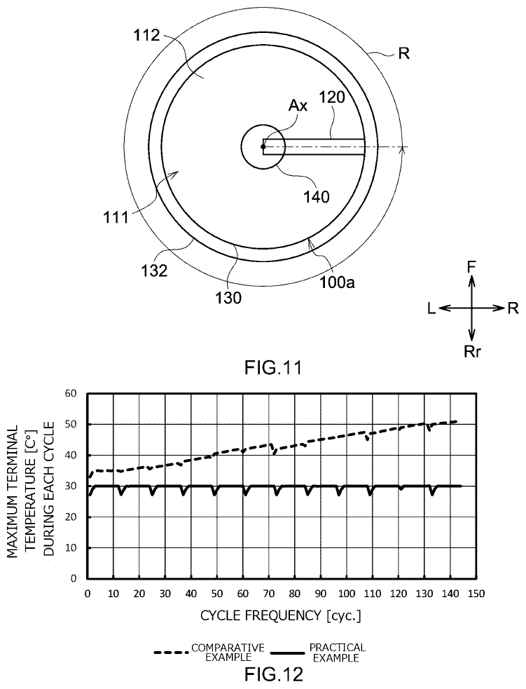

In some embodiments, the grooves 120 at the front end 100a of the probe 100 may form any suitable shape other than a grid pattern. FIG. 10 is a plan view of the front end 100a of the probe 100 provided with a cross-shaped groove 120. FIG. 11 is a plan view of the front end 100a of the probe 100 provided with a linear groove 120. In FIG. 10, the cross-shaped groove 120 is formed to extend through the center of the probe 100. In FIG. 11, the linear groove 120 is formed to extend from the center of the probe 100 to any single point on its outer periphery. Each contact surface 112, which comes into contact with the test object, tends to be larger as the number of grooves 120 decreases. This, however, results in an increase in rotation distance of the probe 100 during removal of a film formed on a surface of the terminal or other portion of the test object. When the cross-shaped groove 120 is formed as illustrated in FIG. 10, the film is removable by rotating the probe 100 in a rotational direction R around the axis Ax by about 90 degrees. When the linear groove 120 is formed as illustrated in FIG. 11, the film is removable by rotating the probe 100 in the rotational direction R around the axis Ax by about 360 degrees.

The probe pin 110 may have any suitable length. The probe pin 110 may have any suitable diameter. From the viewpoint of ensuring a sufficient contact area between the front end 100a of the probe pin 110 and the test object, the front end 100a of the probe pin 110 preferably has a large diameter. The front end 100a of the probe pin 110 may have a diameter of 3 mm or more, preferably has a diameter of 5 mm or more, and more preferably has a diameter of 10 mm or more. In this embodiment, the probe pin 110 has a length of about 50 mm to about 200 mm, inclusive. The probe pin 110 has a circular columnar shape whose diameter is between about 2 mm and about 50 mm, inclusive.

The probe pin 110 is electrically conductive. Any suitable material may be used for the probe pin 110 as long as it enables the probe 100 to achieve the effects of the techniques of the present disclosure. Examples of the material for the probe pin include metal. Typical examples of the material for the probe pin include silver, aluminum, gold, brass, copper, a copper alloy, zinc, a zinc alloy, nickel, palladium, a palladium alloy, and an alloy composed of any of these materials (e.g., a brass alloy). The probe pin may be made of any material other than those mentioned above. Alternatively, a coating may be applied to a surface of the probe pin. Typical examples of the coating include gold plating and nickel plating. From the viewpoint of durability, a nickel coating is preferably applied to the surface of the probe pin that is made of a copper alloy.

The insulator 113 is provided so as to insulate the current supply probe pin 130 and the voltage detection probe pin 140 from each other. Any suitable material may be used for the insulator 113. Any material that is able to prevent direct electrical conduction between the current supply probe pin 130 and the voltage detection probe pin 140 may be used for the insulator 113. Examples of the material for the insulator 113 include an elastomer and plastic. The insulator 113 may be hollow. From the viewpoint of enhancing durability to withstand a temperature rise of the probe 100 during measurement, the insulator 113 is preferably made of plastic.

### Bearing Portion 160

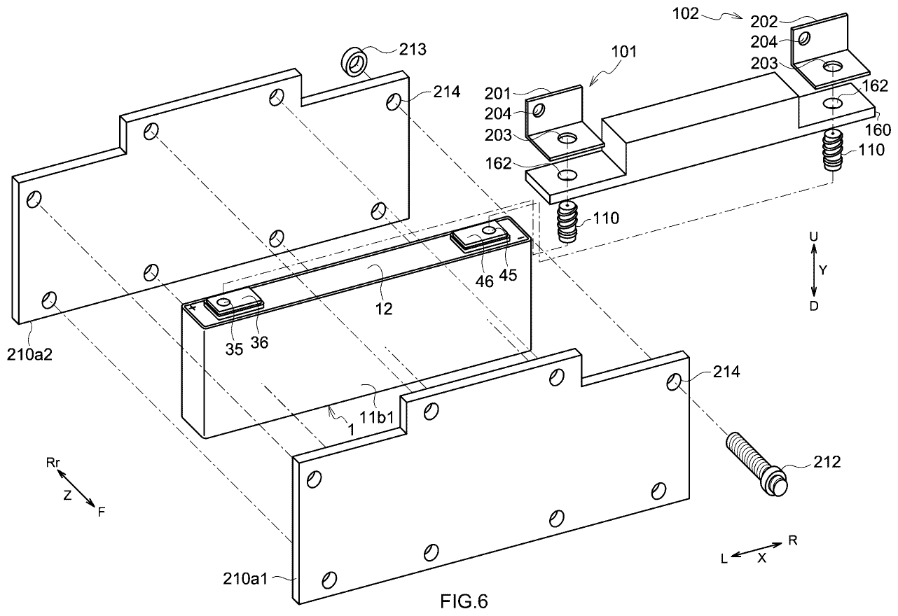

The probe 100 disclosed herein includes the bearing portion 160. The bearing portion 160 holds each probe pin 110 such that the probe pin 110 is rotatable around the axis Ax extending in a longitudinal direction of the probe pin 110 (i.e., the up-down direction Y). The bearing portion 160 includes through holes 162 (see FIG. 6) into each of which a corresponding one of the probe pins 110 is to be inserted. Each probe pin 110 that has been inserted into the corresponding through hole 162 is fixed to the bearing portion 160 with the disengagement stopper 161. The disengagement stopper 161 is fixed to the bearing portion 160 such that each probe pin 110 is rotatable. In this embodiment, the disengagement stopper 161 is disposed adjacent to the rear end 100b of each probe pin 110 (i.e., between the bearing portion 160 and the rear end 100b). This makes it possible to prevent disengagement of each probe pin 110 toward its front end 100a.

The bearing portion 160 may be made of any suitable material. In this embodiment, the probe pins 110 are inserted into the through holes 162 of the bearing portion 160 made of metal. Although not illustrated in detail, an insulator may be provided between each probe pin 110 and the bearing portion 160. Examples of the material for the bearing portion may include a non-conductive material, such as plastic.

The bearing portion 160 fixes each probe pin 110 in orientation such that each probe 100 abuts against the test object. In this embodiment, the orientation of each probe pin 110 is fixed such that the longitudinal direction of each probe 100 is substantially perpendicular to an extension direction of a sealing plate 12 of the lithium ion secondary battery 1 (see FIG. 6). As used herein, the term “substantially perpendicular”, which indicates the orientation of each probe or probe pin, is not limited to a strictly vertical direction but may refer to a direction inclined by a few or several degrees. Because what is required is to ensure conduction between each probe 100 and the test object, the longitudinal direction of each probe 100 may be inclined by, for example, an angle of two degrees or less relative to the extension direction of the sealing plate 12 of the lithium ion secondary battery 1.

### Pressing Member 150

The probe 100 includes the pressing member 150. The pressing members 150 press the probe pin 110 such that the probe pin 110 comes into direct contact with the test object (i.e., the lithium ion secondary battery 1, or more specifically, the positive terminal 35 or negative terminal 45 of the lithium ion secondary battery 1). In addition to the previously described pressing member 150 (which may hereinafter be referred to as a “first pressing member 151”), the probe 100 may further include another pressing member 150 (which may hereinafter be referred to as a “second pressing member 152”). In this embodiment, the probe 100 includes the first pressing member 151 to press the current supply probe pin 130 against the lithium ion secondary battery 1. The probe 100 further includes the second pressing member 152 to press the voltage detection probe pin 140 against the lithium ion secondary battery 1. In this embodiment, the pressing members 150 (i.e., the first pressing member 151 and the second pressing member 152) are springs. Thus, a repulsive force is used to press the probe pin 110 against the test object. Each spring may exert any suitable repulsive force within a range that does not significantly impair the effects achieved by the techniques of the present disclosure. The repulsive force of each spring varies depending on, for example, a material used for each spring, allowing adjustment of a contact pressure exerted between the probe pin 110 and the test object. The pressing members 150, however, are not limited to this arrangement. Each pressing member may be, for example, a weight or rubber. Alternatively, the probe pin 110 may be electrically pressed against the test object by an actuator 170. Optionally, the probe pin 110 may be pressed against the test object by manually applying a force to the probe pin 110.

The first pressing member 151 is disposed outside the current supply probe pin 130. The first pressing member 151 includes a rear end 151b attached to a lower surface of the bearing portion 160. The first pressing member 151 includes a front end 151a attached to the projection 132 such that the front end 151a presses the projection 132. The front end 100a of the probe pin 110 is brought into contact with the test object, which compresses the first pressing member 151, causing the front end 151a to push back the projection 132.

As illustrated in FIG. 2, the second pressing member 152 is disposed inside the current supply probe pin 130. The second pressing member 152 includes a rear end 152b attached to a portion of the probe pin 110 located inside its rear end 100b. The second pressing member 152 includes a front end 152a attached to a rear end of the voltage detection probe pin 140 such that the front end 152a presses the rear end of the voltage detection probe pin 140. The front end 100a of the probe pin 110 is pressed against the corresponding one of the positive and negative terminals 35 and 45 of the lithium ion secondary battery 1, which compresses the second pressing member 152, causing the voltage detection probe pin 140 to be pushed back against the lithium ion secondary battery 1.

The first and second pressing members 151 and 152 may exert any forces (e.g., any repulsive forces) that push the probe pin 110 against the test object, as long as they do not significantly impair the effects achieved by techniques of the present disclosure. In this embodiment, the repulsive force of the second pressing member 152 is set lower than that of the first pressing member 151. As illustrated in FIG. 2, with the probe pin 110 not in abutment with the corresponding terminal of the lithium ion secondary battery 1, the front end of the voltage detection probe pin 140 protrudes from the front end of the current supply probe pin 130. Setting the repulsive force of the second pressing member 152 lower than that of the first pressing member 151 allows the voltage detection probe pin 140 to be quickly pushed into the hollow portion 131 of the current supply probe pin 130. The forces to be exerted by the first and second pressing members 151 and 152 to push the probe pin 110 against the test object, however, are not limited to those described above. The first and second pressing members 151 and 152 may exert similar forces that push the probe pin 110 against the test object.

### Actuator 170

In some embodiments, the probe 100 includes the actuator 170. The actuator 170 includes a mechanism to rotate the probe pin 110. The actuator 170 may include not only the mechanism to rotate the probe pin 110 but also a mechanism to push the front end 100a of the probe pin 110 against the test object (i.e., a mechanism to move the front end 100a of the probe pin 110 upward and downward). In one such embodiment, the actuator 170 is an electric motor. Because the present disclosure relates to probes, a structure, configuration, or arrangement of the actuator 170 will not be described in detail. In this embodiment, the actuator 170 holds the attachment portion 133. Thus, rotative power generated by the actuator 170 is transmittable to the probe pin 110. The current supply probe pin 130 and the voltage detection probe pin 140 each rotate around its axis extending in the longitudinal direction. As illustrated in FIG. 1, the probe pin 110 rotates around the axis Ax in the rotational direction R. The rotational direction R may be a clockwise or counterclockwise direction. The actuator 170 is not limited to an electric motor. In one example, the actuator 170 may be operated manually. In this case, the attachment portion 133 is pinched and rotated manually.

### Test Object

In some embodiments, examples of using the probe disclosed herein may include measurement or detection of, for example, an electric current and/or a voltage of the test object. In one such embodiment, an electricity storage device (e.g., the lithium ion secondary battery 1) is a typical test object for which the probe according to the present disclosure is to be used. The probe 100 is capable of detecting an electric current and a voltage of the lithium ion secondary battery 1. As used herein, the term “electricity storage device” is a concept encompassing a device that is charged and discharged by movement of charge carriers between a pair of electrodes (i.e., positive and negative electrodes). Specifically, the term “electricity storage device” encompasses not only batteries, such as secondary batteries (e.g., lithium ion secondary batteries, nickel-metal hydride batteries, and nickel-cadmium batteries) but also capacitors (or physical batteries), such as lithium ion capacitors and electric double layer capacitors. As used herein, the term “lithium ion secondary battery” refers to an electricity storage device that involves using lithium ions as charge carriers and is repeatedly chargeable and dischargeable by movement of electric charges between positive and negative electrodes, which is accompanied by migration of the lithium ions. The test object is not limited to an electricity storage device. Examples of the test object include a capacitor.

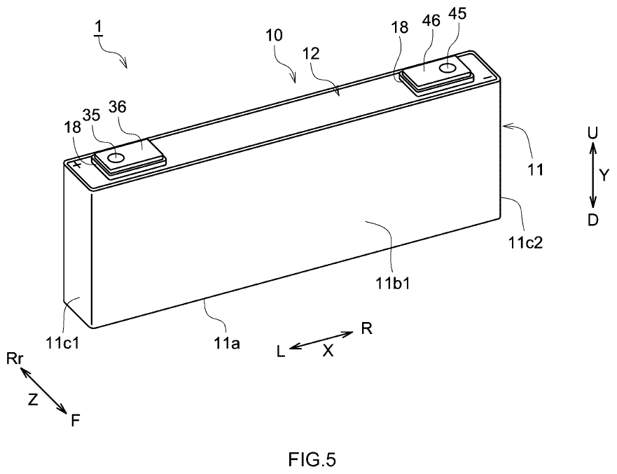

FIG. 5 is a perspective view of the lithium ion secondary battery 1 serving as the test object. As illustrated in FIG. 5, the lithium ion secondary battery 1 in this embodiment includes a case 10 containing: an electrode assembly including a positive electrode and a negative electrode; and an electrolyte. The case 10 includes a body 11 and the sealing plate 12. The body 11 includes: a bottom surface 11a; a pair of wide surfaces 11b1 and 11b2 facing each other; and a pair of narrow surfaces 11cl and 11c2 facing each other. The body 11 includes an opening facing the bottom surface 11a. In this embodiment, the opening is sealed with the sealing plate 12. The body 11 and the sealing plate 12 are subjected to welding, such as laser welding, and thus sealed (or more specifically, hermetically sealed).

As illustrated in FIG. 5, the case 10 in this embodiment is cuboidal with a flat rectangular profile. The case 10 may be made of any of materials used for this type of electricity storage device known in the art. In one example a lightweight and highly thermally conductive metallic material, such as aluminum, is used as the material for the case 10. The case 10, however, may be modified in configuration, structure, or arrangement. A laminated film exhibiting plasticity, for example, may be used as the case.

The lithium ion secondary battery 1 includes the positive and negative terminals 35 and 45 for external connection. The positive and negative terminals 35 and 45 are provided so as to be exposed outside the case 10. As illustrated in FIG. 5, the positive and negative terminals 35 and 45 in this embodiment are attached to the sealing plate 12 through gaskets 18. Although not illustrated in detail, an internal structure of the case 10 involves the positive terminal 35 electrically connected to the positive electrode inside the case 10. The negative terminal 45 is electrically connected to the negative electrode inside the case 10. These terminals are made of electrically conductive metal. Aluminum or an alloy composed mainly of aluminum, for example, may be used as the positive terminal 35. Copper or a copper alloy, for example, may be used as the negative terminal 45. An insulating material that exhibits high chemical resistance and/or high weather resistance may be used as a material for the gaskets 18.

As illustrated in FIG. 5, in this embodiment, a positive electrode external terminal conductive member 36 and a negative electrode external terminal conductive member 46, each having a plate shape, are attached to an outer surface of the sealing plate 12. When two or more lithium ion secondary batteries 1 are electrically connected to each other, electrically conductive members, such as busbars, are attached to the positive electrode external terminal conductive member 36 and the negative electrode external terminal conductive member 46. The positive electrode external terminal conductive member 36 is electrically connected to the positive terminal 35. The negative electrode external terminal conductive member 46 is electrically connected to the negative terminal 45. The positive electrode external terminal conductive member 36 and the negative electrode external terminal conductive member 46 are preferably made of metal, and more preferably made of, for example, aluminum or an aluminum alloy. The positive electrode external terminal conductive member 36 and the negative electrode external terminal conductive member 46 are optional and may be omitted in other embodiments.

### Testing Apparatus for Voltage or Other Characteristic of Lithium Ion Secondary Battery 1

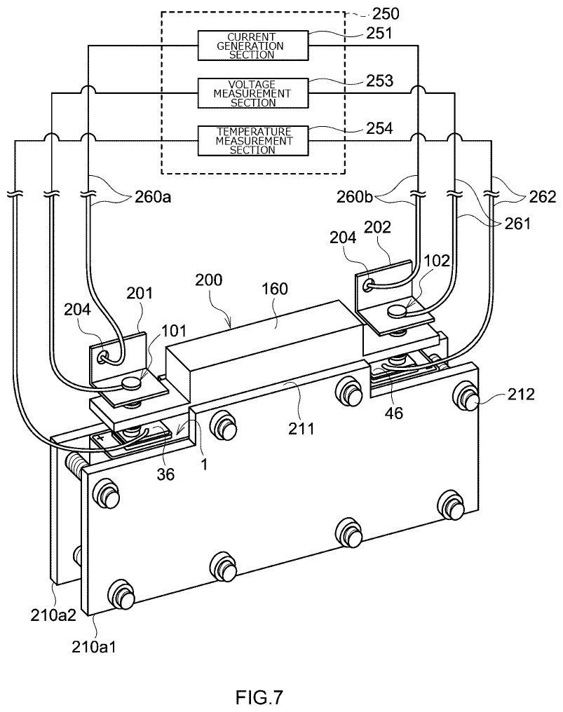

FIG. 6 is an explanatory diagram illustrating an installation method for the probes 100 for measurement of the voltage or other characteristic of the lithium ion secondary battery 1. FIG. 7 is an explanatory diagram illustrating probe use conditions. FIGS. 6 and 7 schematically illustrate an apparatus assembling method when an electric characteristic of the lithium ion secondary battery 1 is to be measured. In FIG. 6, the apparatus illustrated in FIG. 7 is disassembled to clarify how the probe unit 200 is to be installed. In this embodiment, the probes 100 are included in the probe unit 200 to be connected to the positive and negative terminals 35 and 45 of the lithium ion secondary battery 1. The probe unit 200 includes: a first probe 101 to be connected to a first electrode; and a second probe 102 to be connected to a second electrode. The second electrode differs in polarity from the first electrode. For the sake of convenience, the following description is based on the assumption that the positive terminal 35 is used as example of the first electrode and the negative terminal 45 is used as an example of the second electrode. The probe 100 to be connected to the positive terminal 35 is defined as the “first probe 101”. The probe 100 to be connected to the negative terminal 45 is defined as the “second probe 102”.

As illustrated in FIG. 6, the probe unit 200 includes: the first probe 101 to be connected to the positive terminal 35 of the lithium ion secondary battery 1; and the second probe 102 to be connected to the negative terminal 45 of the lithium ion secondary battery 1. The first and second probes 101 and 102 are similar in configuration to the probes 100 described above. In this embodiment, the bearing portion 160 is a plate-shaped member that extends along the sealing plate 12 of the lithium ion secondary battery 1. The bearing portion 160 is provided with the through holes 162, the number of which is two. The first probe 101 is inserted into one of the through holes 162, and the second probe 102 is inserted into the other through hole 162. The through holes 162 are provided such that one of the through holes 162 faces the positive terminal 35 and the other through hole 162 faces the negative terminal 45. The first and second probes 101 and 102 share the bearing portion 160. The probe pin 110 of the first probe 101 is inserted into the through hole 162 that faces the positive terminal 35. The probe pin 110 of the second probe 102 is inserted into the through hole 162 that faces the negative terminal 45. The bearing portion 160, however, may have any suitable shape other than that described above.

As illustrated in FIG. 6, the testing apparatus in this embodiment includes a pair of holding plates 210al and 210a2 between which the lithium ion secondary battery 1 is to be sandwiched in its thickness direction (i.e., the front-rear direction Z). The pair of holding plates 210al and 210a2 abut against the wide surfaces 11b1 and 11b2 of the lithium ion secondary battery 1. The pair of holding plates 210al and 210a2 are larger than the wide surfaces 11b1 and 11b2 against which the holding plates 210al and 210a2 abut. The pair of holding plates 210al and 210a2 are provided with through holes 214 into each of which a bolt 212 is to be inserted. As illustrated in FIG. 7, each bolt 212 is inserted into corresponding ones of the through holes 214 of the pair of holding plates 210al and 210a2, and each bolt 212 and an associated nut 213 are tightened together, thereby fixing the lithium ion secondary battery 1 between the holding plates 210al and 210a2. The pair of holding plates 210al and 210a2 include protrusions 211 to restrain the probe unit 200. The protrusions 211 hold the bearing portion 160 of the probe unit 200 therebetween, thus securing the probe unit 200. Any suitable material may be used for the holding plates 210al and 210a2. The holding plates 210al and 210a2 are preferably made of a high-strength material. In this embodiment, the holding plates 210a1 and 210a2 made of metal (e.g., a stainless alloy) are used.

In this embodiment, a first L-shaped metal fitting 201 is attached adjacent to the rear end 100b of the first probe 101. A second L-shaped metal fitting 202 is attached adjacent to the rear end 100b of the second probe 102. As illustrated in FIG. 6, the first and second L-shaped metal fittings 201 and 202 are provided with through holes 203 for attachment of the probe pins 110. The first and second L-shaped metal fittings 201 and 202 are electrically conductive members. The probe pins 110 are passed through the through holes 203 of the first and second L-shaped metal fittings 201 and 202 and attached thereto such that the probe pins 110 are in contact with inner peripheries of the through holes 203. This enables conduction between the probe pins 110 and the lithium ion secondary battery 1. The first and second L-shaped metal fittings 201 and 202 are provided with attachment holes 204 for attachment of current wirings 260a and 260b. As illustrated in FIG. 7, the current wirings 260a and 260b are each connected a corresponding one of the attachment holes 204. A first wire of the current wiring 260a connects a current generation section 251 to the first probe 101. A second wire of the current wiring 260b connects the current generation section 251 to the second probe 102. Thus, charging and discharging currents are supplied to the lithium ion secondary battery 1 through the first and second probes 101 and 102. The actuator 170 and the voltage wiring 261 are attached to each attachment portion 133. The voltage wiring 261 is connected to a voltage measurement section 253. A thermocouple 262 is directly attached to the positive electrode external terminal conductive member 36 and the negative electrode external terminal conductive member 46 of the lithium ion secondary battery 1 by using fasteners (not illustrated). The thermocouple 262 is connected to a temperature measurement section 254. The thermocouple does not necessarily have to be used for temperature measurement. Any suitable temperature sensor known in the art may be used for temperature measurement. In one example, a sensor, such as an infrared sensor, that does not come into direct contact with a measurement object may be used for temperature measurement.

### Measurement Device

Any suitable measurement device may be used as long as it does not significantly impair the effects achieved by the techniques of the present disclosure. Although not illustrated in detail, a measurement device 250 in this embodiment includes the current generation section 251, the voltage measurement section 253, and the temperature measurement section 254. The current generation section 251 is a device to supply an electric current or electric signal to the lithium ion secondary battery 1 through the first probe 101 and/or the second probe 102. In other words, the current generation section 251 is able to function as a power supply. The voltage measurement section 253 is a device to measure a voltage of the lithium ion secondary battery 1. The temperature measurement section 254 is a device to measure a temperature of the object based on signals received from temperature measurement terminals (i.e., the thermocouple 262). Where appropriate, settings on these devices may be suitably adjusted according to a purpose of evaluation of the test object. Examples of the measurement device include an oscilloscope, a charging and discharging device, and a tester.

### Testing Method

The probes 100 described above enable accurate testing of an electric characteristic of the test object. Specifically, using the probes disclosed herein, the present disclosure provides a testing method for testing the electric characteristic of the test object by bringing the ends of the probes into contact with the test object. In this embodiment, the testing method includes: a contact step of bringing the front ends 100a of the probe pins 110 into contact with the positive and negative terminals 35 and 45 of the lithium ion secondary battery 1; a pressing and rotating step of rotating the front ends 100a of the probe pins 110 while pressing the front ends 100a that are in contact with the positive and negative terminals 35 and 45; a supplying step of supplying an electric current or electric signal to the lithium ion secondary battery 1; and a measuring step of measuring the electric characteristic of the lithium ion secondary battery 1 based on an electric signal received from the lithium ion secondary battery 1.

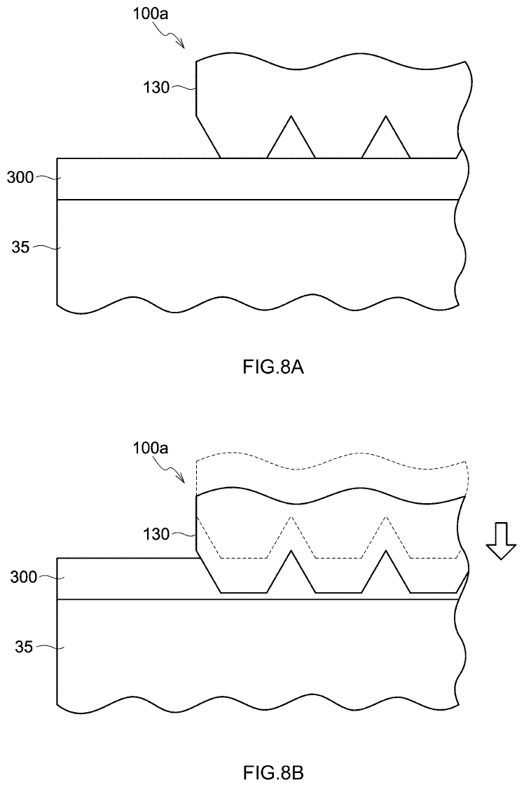

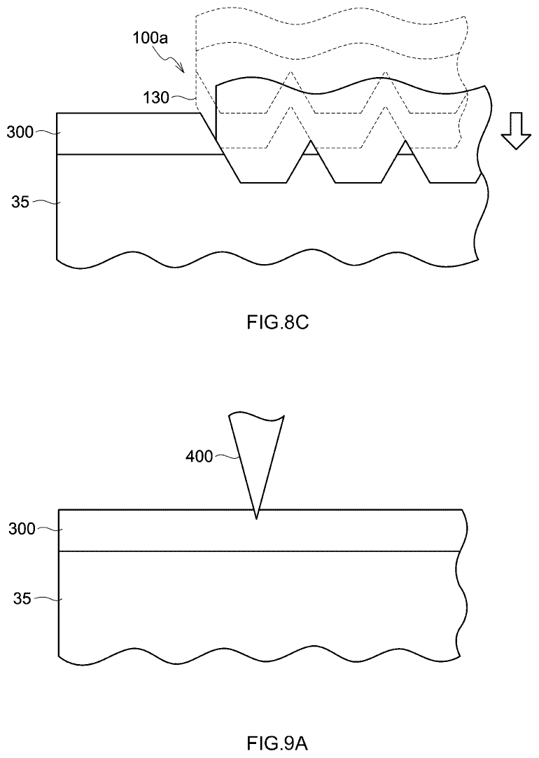

FIG. 8A is an explanatory diagram illustrating the probe 100 (which is the first probe 101 in this embodiment) and the corresponding terminal of the test object (which is the positive terminal 35 of the lithium ion secondary battery 1 in this embodiment) in contact with each other. FIG. 8B is an explanatory diagram illustrating the first probe 101 pressed against the lithium ion secondary battery 1. FIG. 8C is an explanatory diagram illustrating how a film is removed upon rotation of the first probe 101. FIGS. 8A and 8C illustrate a process of removal of the film (which is an oxide film 300 in this embodiment) on a terminal surface in course of following the contact step and the pressing and rotating step (which will be described below). FIG. 8A illustrates the front end 100a of the first probe 101 in contact with the positive terminal 35 during the contact step (which will be described below). FIGS. 8B and 8C illustrate the front end 100a of the first probe 101 that is rotated while being pressed against the positive terminal 35 during the pressing and rotating step (which will be described below). Although the first probe 101 and the positive terminal 35 are illustrated by way of example in FIGS. 8A to 8C, the same applies to the second probe 102 and the negative terminal 45.

### Contact Step

In the contact step, the first probe 101 is brought into contact with the positive terminal 35 of the lithium ion secondary battery 1, and the second probe 102 is brought into contact with the negative terminal 45 of the lithium ion secondary battery 1. As illustrated in FIG. 6, in this embodiment, the first probe 101 and the second probe 102 are fixed through the through holes 162 of the bearing portion 160. In this embodiment, the through holes 162 also serve as a guide that causes the front end 100a of the first probe 101 to face and come into contact with the positive terminal 35 and causes the front end 100a of the second probe 102 to face and come into contact with the negative terminal 45. Placing the probe unit 200 on the sealing plate 12 of the lithium ion secondary battery 1 brings the first probe 101 into contact with the positive terminal 35 and brings the second probe 102 into contact with the negative terminal 45.

### Pressing and Rotating Step

In the pressing and rotating step, the first and second probes 101 and 102, which have been brought into contact with the terminals of the lithium ion secondary battery 1, are rotated while being pressed against the terminals of the lithium ion secondary battery 1. This enables removal of the oxide film 300 formed on the terminals. In this embodiment, the probe unit 200 compresses the first and second pressing members 151 and 152 with its weight, and the repulsive forces of the first and second pressing members 151 and 152 press the front ends 100a against the terminals. Activating the actuator 170 in this state allows the first and second probes 101 and 102 to rotate while their front ends 100a are pressed against the terminals.

Alternatively, a worker may manually rotate each probe 100 while pressing its front end 100a against the corresponding terminal. In one example, the worker wears protective gears such as rubber gloves, pinches the attachment portion 133 of each probe 100, and rotates each probe 100 by a required angle while pressing each attachment portion 133 in a downward direction D.

An example of the pressing and rotating step will be described below with reference to the first probe 101 and the positive terminal 35. As illustrated in FIG. 8A, the front end 100a of the first probe 101 (i.e., the contact portion 111 that comes into contact with the positive terminal 35) is flat. A surface of the positive terminal 35 is covered with the oxide film 300. In the state illustrated in FIG. 8A, the oxide film 300 is present between the first probe 101 and the positive terminal 35. The presence of the oxide film 300 may interfere with accurate measurement. To remove the oxide film 300, the pressing and rotating step first involves pressing the front end 100a of the first probe 101 toward the positive terminal 35 as illustrated in FIG. 8B. This allows the front end 100a of the first probe 101 to sink into the oxide film 300. The pressing and rotating step then involves rotating the first probe 101 around the central axis Ax as illustrated in FIG. 8C. The first probe 101 is rotated while being pressed against the positive terminal 35. Thus, the oxide film 300 is shaved off by the edges 121 of the grooves 120. The oxide film 300 that has been shaved off is scooped by the rake faces 122. Accordingly, the first probe 101 is pressed toward the positive terminal 35 while the oxide film 300 is removed. As a result, the contact portion 111 comes into direct contact with the positive terminal 35, enabling accurate measurement of the electric characteristic of the lithium ion secondary battery 1.

In the pressing and rotating step, any suitable force may be applied to press each probe 100 against the corresponding terminal as long as it does not significantly impair the effects achieved by the techniques of the present disclosure. The oxide film, contaminant, or other substance tends to be removed as the force to press each probe 100 against the corresponding terminal increases, which means that this force is preferably as great as possible. The rotation distance by which each probe 100 is to be rotated may be any distance within a range that does not significantly impair the effects achieved by the techniques of the present disclosure. The probe 100 whose front end 100a includes the grooves 120 arranged in a grid pattern as illustrated in FIG. 3 is able to remove the oxide film 300 upon rotation of the probe 100 in the rotational direction R by an angle α. The angle α is illustrated by way of example and should not be construed as limiting maximum and minimum values of the rotation distance. The rotational direction R may be a clockwise or counterclockwise direction.

In some embodiments, the pressing and rotating step may be performed before or after the supplying step (which will be described below). The pressing and rotating step may be performed before the measuring step (which will be described below). The pressing and rotating step may be performed between the supplying step and the measuring step. The pressing and rotating step may be performed just once or more than once.

### Supplying Step

In the supplying step, an electric current, electric signal, or other signal, for example, is supplied to the test object. In this embodiment, the current generation section 251 of the measurement device 250 supplies a charging or discharging current to the first probe 101 or the second probe 102 through the current wiring 260a or the current wiring 260b.

In one example of the supplying step, the electricity storage device is charged at constant current until a predetermined charging time (typically between 10 seconds and 5400 seconds) elapses. In another example, the electricity storage device is charged at constant current until a predetermined voltage (e.g., a voltage of between about 3.5 V and about 4.5 V) is reached. The supplying step may involve performing constant-current/constant-voltage charging using these charging methods in combination. During discharging, the electricity storage device may be discharged at constant current until a predetermined discharging time (typically between 10 seconds and 5400 seconds) elapses or may be discharged at constant current until a predetermined voltage (e.g., a voltage of between about 2.5 V and about 3.5 V) is reached. The supplying step may involve performing constant-current/constant-voltage discharging using these discharging methods in combination. In this embodiment, the electric current supplied from the current generation section 251 is passed to the second probe 102 connected to the negative terminal 45 of the lithium ion secondary battery 1, thus charging the lithium ion secondary battery 1. The electric current supplied from the current generation section 251 is passed to the first probe 101 connected to the positive terminal 35 of the lithium ion secondary battery 1, thus discharging electric charges from the lithium ion secondary battery 1.

In the supplying step, any type and magnitude (or amount) of electric current, electric signal, or other signal may be supplied to the test object. The type and magnitude of electric current, electric signal, or other signal to be supplied may be suitably selected in accordance with the test object and a purpose of testing. For example, when a charging and discharging test is conducted on a large-size electricity storage device installable on a vehicle or other transport means (a typical example of which is an electricity storage device with a capacity of 50 Ah or more), the supplying step preferably involves passage of a high electric current. An electric current of any suitable magnitude may be passed during charging and discharging test. During charging, the electricity storage device is preferably charged at a constant current of 20 A or more, more preferably charged at a constant current of 50 A or more, and most preferably charged at a constant current of 100 A or more. During discharging, the electricity storage device is preferably discharged at a constant current of 20 A or more, more preferably discharged at a constant current of 50 A or more, and most preferably discharged at a constant current of 100 A or more.

### Measuring Step

In the measuring step, the electric characteristic or other characteristic of the test object is measured, for example, based on an electric signal or other signal received from the test object. The voltage of the test object, to which an electric current is supplied through the current supply probe pin 130 of the probe 100, is measured using the voltage detection probe pin 140. An electric signal from the voltage detection probe pin 140 is sent to the voltage measurement section 253 through the voltage wiring 261. The resistance value between the probe 100 and the test object is measured based on a value of electric current supplied through the current supply probe pin 130 and a value of voltage measured using the voltage detection probe pin 140.

Exemplary electric characteristic measurement in this embodiment will be described below. In this embodiment, the first probe 101 is connected to the positive terminal 35. During discharging, an electric current is supplied from the current generation section 251 to the first probe 101, thus discharging the lithium ion secondary battery 1. A voltage at the positive terminal 35 in this case is measured by the voltage measurement section 253 through the voltage detection probe pin 140 of the first probe 101. Thus, a voltage during discharging is measurable. The second probe 102 is connected to the negative terminal 45. During charging, an electric current is supplied from the current generation section 251 to the second probe 102, thus charging the lithium ion secondary battery 1. A voltage at the negative terminal 45 in this case is measured by the voltage measurement section 253 through the voltage detection probe pin 140 of the second probe 102. Thus, a voltage during charging is measurable. In addition, a voltage between the positive and negative terminals 35 and 45 of the lithium ion secondary battery 1 is measurable using the first and second probes 101 and 102. As a result, resistance between the positive and negative terminals 35 and 45 of the lithium ion secondary battery 1 is determinable.

One example of the measuring step involves measuring (or recording), at predetermined recording intervals, voltage variations with respect to a charging time or discharging time during the supplying step described above. The recording intervals are preferably 0.1 sec or less (i.e., 100 msec or less). The voltage variations are recorded in a manner that includes a discharging period used for resistance calculation. The voltage variations may be recorded immediately after start of discharging. Alternatively, settings may be made such that recording starts after lapse of a predetermined time from the start of discharging. Measuring or recording the voltage variations in the above-described manner provides a chart in which the voltage variations are plotted with respect to the discharging time.

The measuring step includes a step of calculating a measurement result (e.g., a resistance value) from electric signals or other signals received from the test object. In one example, from a discharging current value during discharging and a voltage drop value during the set discharging period, resistance of the lithium ion secondary battery 1 during the predetermined discharging period is calculable in accordance with Ohm's law (V=IR, where V represents voltage, I represents electric current, and R represents resistance).

### Comparison Between Probe Needle 400 Known in the Art and Probe 100 According to Present Disclosure

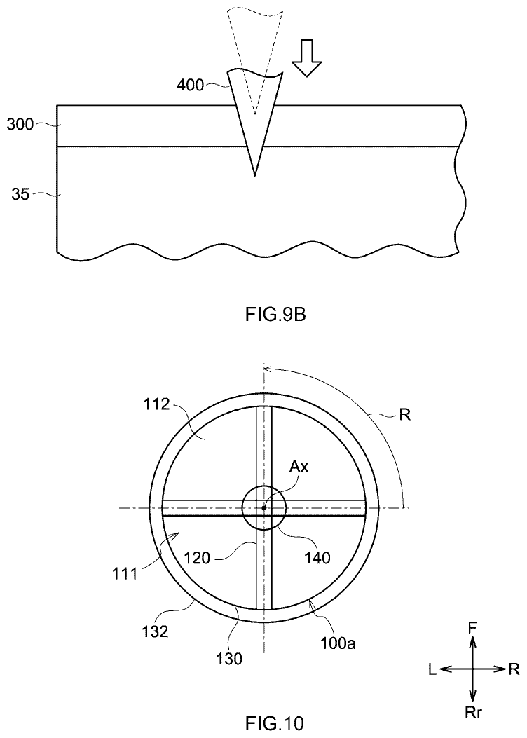

FIG. 9A is an explanatory diagram schematically illustrating a probe needle 400 known in the art and the positive terminal 35 of the lithium ion secondary battery 1 that are in contact with each other. FIG. 9B is an explanatory diagram schematically illustrating the probe needle 400 known in the art that is pressed against the positive terminal 35 of the lithium ion secondary battery 1. FIGS. 9A and 9B illustrate a process of establishing conduction between a probe, which includes the probe needle 400 known in the art, and the terminal of the test object.

The probe is connected to a surface of the terminal or other portion of the test object and used to measure the electric characteristic or other characteristic of the test object. The terminal of the test object is typically made of a metallic material, such as aluminum. Thus, flux is applied to the surface of the terminal, or an insulative film, such as an oxide film, is likely to be formed on the surface of the terminal depending on an ambient environment. The film hinders conduction between the probe and the terminal. This results in an increase in resistance value between the probe and the terminal, which unfortunately leads to a rise in temperature of the terminal and eventually to a rise in temperature of the test object. Such a temperature rise may cause degradation and/or voltage drop of the test object, which may prevent accurate measurement.

Accordingly, a conceivable approach is to remove the film formed on the surface of the terminal. As illustrated in FIG. 9A, for example, the oxide film 300 is formed on the surface of the terminal (which is the positive terminal 35 of the lithium ion secondary battery 1 in this embodiment). The probe needle 400 known in the art includes a needle-shaped tip. As illustrated in FIG. 9B, the probe needle 400 is pressed into the positive terminal 35. This causes a sharply projecting portion of the tip to pierce through the oxide film 300 and come into direct contact with the positive terminal 35. The test object (e.g., an electricity storage device), however, tends to increase in size and capacity. For example, conducting an evaluation test, such as a charging and discharging test, on a large-size electricity storage device necessitates passage of a high electric current (typically 20 A or more). Such a case requires transmitting or receiving a high electric current or a large quantity of electric signal or other signal. A small contact region between each probe and the test object may cause a rise in terminal temperature and/or a voltage drop during passage of a high electric current. To cope with these problems, the inventors have conducted extensive research and have found probes suitable for removal of a film formed on a surface of a test object and passage of a high electric current.

In the foregoing embodiment, each probe includes: the electrically conductive probe pin 110; the pressing member 150 to press the probe pin 110 against the test object; and the bearing portion 160 holding the probe pin 110 such that the probe pin 110 is rotatable around the axis Ax extending in the longitudinal direction of the probe pin 110 (i.e., the up-down direction Y). The front end 100a of the probe pin 110 includes: the flat contact portion 111 to be brought into direct contact with the test object; and the grooves 120 extending from the center of the front end 100a toward its outer periphery. This probe is rotatable while the probe pin 110 is pressed against the test object. Because the front end 100a of the probe pin 110 is provided with the grooves 120, a film, such as the oxide film 300, formed on the surface of the test object is removable. Thus, the front end 100a of the probe pin 110 is allowed to come into direct contact with the test object without any film present therebetween. This direct contact is able to limit an increase in resistance value between the probe pin 110 and the test object. The front end 100a of the probe pin 110 is flat. Accordingly, the probe 100 and the test object would be likely to maintain a constant or substantially constant temperature if an electric current, an electric signal, or other signal is passed in large quantity. The probe 100 whose front end is flat is less prone to damage the surface of the test object than a probe whose front end is sharp.

In the foregoing embodiment, each probe is configured such that the contact area between the flat contact portion 111 and the test object is at least 0.5 mm² or more. This more reliably secures the contact surfaces 112 through which the probe 100 comes into contact with the test object. As a result, the probe 100 is able to establish stable contact with the test object, enabling more reliable passage of a high electric current. The front end 100a of the probe pin 110 includes the flat contact surfaces 112 defined by the grooves 120. The front end 100a of the probe pin 110 comes into contact with the test object through the contact surfaces 112. Thus, the film is removable by rotating the probe 100 by a short distance, making it possible to more reliably bring the contact surfaces 112 of the front end 100a of the probe pin 110 into direct contact with the test object.

In the foregoing embodiment, the disengagement stopper 161 to prevent disengagement of the probe pin 110 is disposed adjacent to the rear end 100b of the probe pin 110. The projection 132 projecting along the outer circumference of the probe pin 110 is disposed adjacent to the front end 100a of the probe pin 110. The pressing member 150 (or more specifically, the first pressing member 151) is disposed between the bearing portion 160 and the projection 132. In one example, the pressing member 150 is a spring. Upon contact of the front end 100a of the probe pin 110 with the test object, a load is applied to the front end 100a from the test object. This load compresses the pressing member 150, and then the pressing member 150 presses the projection 132 toward the test object in an attempt to return to its original condition. In other words, the pressing member 150 presses the probe pin 110 against the test object with its repulsive force. As a result, the probe 100 is able to establish more stable contact with the test object.

In the foregoing embodiment, each probe pin 110 includes: the current supply probe pin 130 to supply an electric current; the voltage detection probe pin 140 to detect a voltage; and the insulator 113 insulating the current supply probe pin 130 and the voltage detection probe pin 140 from each other. This allows voltage measurement while a high electric current is passed.

In the foregoing embodiment, the current supply probe pin 130 has a cylindrical shape. The voltage detection probe pin 140 is disposed inside the current supply probe pin 130, with the insulator 113 interposed therebetween. Thus, the current supply probe pin 130 and the voltage detection probe pin 140 are able to come into stable contact with the test object.

Using the probes described above, the present disclosure provides a probe unit to be connected to an electricity storage device. In the foregoing embodiment, the probe unit includes: the first probe 101 to be connected to the first electrode; and the second probe 102 to be connected to the second electrode. The first probe 101 includes: a first probe pin that is electrically conductive; a first probe pressing member to press the first probe pin against the first electrode; and a first probe bearing portion holding the first probe pin such that the first probe pin is rotatable around an axis extending in a longitudinal direction of the first probe pin. The front end 100a of the first probe pin includes: the flat contact portion 111 to be brought into direct contact with the test object; and the grooves 120 extending from the center of the front end 100a toward its outer periphery. The second probe 102 includes: a second probe pin that is electrically conductive; a second probe pressing member to press the second probe pin against the second electrode; and a second probe bearing portion holding the second probe pin such that the second probe pin is rotatable around an axis extending in a longitudinal direction of the second probe pin. The front end 100a of the second probe pin includes: the flat contact portion 111 to be brought into direct contact with the test object; and the grooves 120 extending from the center of the front end 100a toward its outer periphery. Terminals of the electricity storage device contain metal (e.g., aluminum). This facilitates formation of a film, such as the oxide film 300. The film, such as the oxide film 300, present on surfaces of the terminals is removable by rotating the first probe 101 and the second probe 102 each being pressed against the corresponding terminal. As a result, the probe unit 200 establishes a favorable connection with the electricity storage device.

Using the probe unit described above, the present disclosure provides an electricity storage device testing apparatus. In the foregoing embodiment, the electricity storage device testing apparatus includes: the probe unit 200; the holding plates 210al and 210a2 to hold the electricity storage device and the probe unit 200; the current generation section 251 to supply an electric current or electric signal through the first probe 101 and/or the second probe 102; and a measurement section to measure an electric characteristic of the electricity storage device based on an electric signal received from the electricity storage device. The probe unit 200 removes the film that may be formed on the surfaces of the terminals of the electricity storage device. The probe unit 200 is thus able to limit a rise in terminal temperature and prevent or reduce degradation of the electricity storage device. As a result, the probe unit 200 establishes a favorable connection with the electricity storage device. The electricity storage device and the probe unit 200 are fixed with the holding plates 210al and 210a2 in such a manner that the electricity storage device and the probe unit 200 are connected to each other. The probe unit 200 thus allows supply of a high electric current or electric signal from the current generation section 251 to the electricity storage device through the first probe 101 and the second probe 102. The measurement section is able to measure, for example, a voltage when the electric current or electric signal is supplied to the electricity storage device. This arrangement makes it possible to more accurately conduct a test, such as an evaluation test (e.g., a charging and discharging test), on the electricity storage device.

Using the probes disclosed herein, a favorable connection is established with the test object as described above. Accordingly, the present disclosure provides a testing method for testing the electric characteristic of the test object by bringing the front ends of the probes into contact with the test object. The testing method disclosed herein includes: the contact step of bringing the front ends 100a of the probes 100 into contact with the terminals of the test object; the pressing and rotating step of rotating the front ends 100a of the probes 100 while pressing the front ends 100a that are in contact with the terminals; the supplying step of supplying an electric current or electric signal to the test object; and the measuring step of measuring the electric characteristic of the test object based on an electric signal received from the test object. The testing method involves pressing the probes 100 that are in contact with the terminals of the test object, thereby causing the front ends 100a of the probes 100 to sink into films, such as oxide films or contaminants, present on the surfaces of the terminals. The testing method then involves rotating the probes 100 pressed against the terminals, thereby bringing the probes 100 into direct contact with the terminals while removing the films. Consequently, the testing method is able to ensure favorable conduction between the probes 100 and the test object.

In the foregoing embodiment, the supplying step involves passage of a constant current of at least 20 A or more. The probes 100 maintain favorable conduction with the test object. This enables accurate measurement of the electric characteristic or other characteristic during an evaluation test of a large-size or high-capacity electricity storage device.

Using the testing method disclosed herein, the present disclosure provides a highly reliable electricity storage device as described above. Accordingly, the present disclosure provides an electricity storage device manufacturing method including the testing process described above. The electricity storage device manufacturing method includes: a step of preparing an electricity storage device; a contact step of bringing the front ends 100a of the probes 100 into contact with terminals of the electricity storage device; a pressing and rotating step of rotating the front ends 100a of the probes 100 while pressing the front ends 100a that are in contact with the terminals; a supplying step of supplying an electric current or electric signal to the electricity storage device; and a measuring step of measuring an electric characteristic of the electricity storage device based on an electric signal received from the electricity storage device. The manufacturing method is able to manufacture the electricity storage device that has undergone a more accurate evaluation test. In addition, the manufacturing method is able to limit, for example, a rise in cell temperature when a high electric current is passed during evaluation of the electricity storage device. Accordingly, the manufacturing method is able to prevent or reduce degradation of the electricity storage device. Consequently, the manufacturing method allows passage of a high electric current and is thus advantageous in manufacturing a large-size or high-capacity electricity storage device.

Although the preferred embodiments of the present disclosure have been described above with reference to the drawings, the above description should not be construed as limiting the scope of the present disclosure, and various modifications may naturally be made to the foregoing embodiments.

The present disclosure will be described below with reference to a practical example and a comparative example. The following description, however, is not intended to limit the scope of the present disclosure to the practical example described below.

### Preparation of Lithium Ion Secondary Battery

First, a lithium ion secondary battery with a capacity of 180 Ah was prepared as a test object. The lithium ion secondary battery prepared includes a rectangular case and positive and negative terminals exposed outside the rectangular case. Aluminum was used as a material for the positive and negative terminals. Upon exposure to the atmosphere, the positive and negative terminals formed oxide films on their surfaces.

### Practical Example: Fabrication of Sample Probes and Probe Unit

Each sample probe prepared in the practical example is equipped with a mechanism to remove the oxide film by rotating a front end of each sample probe while pressing the front end against a corresponding one of the terminals of the lithium ion secondary battery as in the foregoing embodiment. Each cylindrical current supply probe pin prepared in the practical example is made of a copper alloy, has nickel plating applied to its surface, has a length of 70 mm, an outer diameter of 20 $, and an inner diameter of 7, and includes a flat contact portion that comes into direct contact with the corresponding terminal of the lithium ion secondary battery and that has an area of 315 mm². Each voltage detection probe pin prepared in the practical example is made of a copper alloy, has nickel plating applied to its surface, has a length of 70 mm and an outer diameter of 7 φ, and includes a flat contact portion that comes into direct contact with the corresponding terminal of the lithium ion secondary battery and that has an area of 35 mm². The front end of each sample probe (which includes the current supply probe pin and the voltage detection probe pin) was subjected to cutting such that grooves were formed in a grid pattern. Each voltage detection probe pin having a plastic insulator wound around its outer periphery was inserted into the corresponding current supply probe pin. The number of sample probes prepared in this manner is two. A bearing portion prepared in the practical example is a long stainless plate including through holes disposed to face the positive and negative terminals of the lithium ion secondary battery. A probe unit in the practical example was prepared by inserting the sample probes into the through holes and fixing the sample probes such that the sample probes were rotatable. Pressing members prepared in the practical example are springs.

The front ends of the sample probes were brought into contact with the positive and negative terminals of the lithium ion secondary battery prepared. This process involved restraining the lithium ion secondary battery and the probe unit at a restraining pressure of 12.9 kN by using holding plates. The current supply probe pin of each sample probe was connected to a current generator (i.e., a power supply). The voltage detection probe pin of each sample probe was connected to a voltage detector. As the power supply and measuring equipment, a 5 V, 180 A power supply system Sys 18 manufactured by NIPPON STEEL TEXENG. CO., LTD. was used. A thermocouple extending from a temperature measuring device was connected to the positive and negative terminals. As the temperature measuring device, GL360 manufactured by GRAPHITEC was used. Thus, a testing apparatus was assembled.

### Removal of Oxide Film

After the testing apparatus was assembled as described above, the oxide film was removed by manually rotating each sample probe by about 10 degrees while pressing each sample probe against the corresponding terminal.

### Charging and Discharging Test

A charging and discharging test was conducted on the lithium ion secondary battery. The charging and discharging test involved performing a cycle test and an electric characteristic measuring process alternately. The electric characteristic measuring process (which is described in Step 2) was performed before execution of a cycle (which is described in Step 1) and after execution of the 36th, 72th, 108th, and 144th cycles. Terminal temperatures were continuously measured during charging and discharging test irrespective of the cycles.

### Step 1

The cycle test involves performing constant-current charging at 1 C for 600 seconds, and then performing discharging at 0.3 C by a capacity equal to that used for charging. This charging and discharging process is defined as one cycle.

### Step 2

The electric characteristic measuring process involves performing discharging at a constant current value from the same voltage each time, and measuring resistance from a voltage determined after 10 seconds.

### Comparative Example: Control Probes and Control Probe Unit

Each control probe prepared in the comparative example is able to press its front end against the corresponding terminal of the lithium ion secondary battery but is non-rotatably fixed and thus not completely equipped with a mechanism to remove an oxide film. Each cylindrical current supply probe pin prepared in the comparative example is made of a copper alloy, has nickel plating applied to its surface, has a length of 70 mm, an outer diameter of 20 φ, and an inner diameter of 8 φ, and includes a flat contact portion that comes into direct contact with the corresponding terminal of the lithium ion secondary battery and that has an area of 315 mm². Each voltage detection probe pin prepared in the comparative example is made of a copper alloy, has nickel plating applied to its surface, has a length of 70 mm and an outer diameter of 7.5 φ, and includes a flat contact portion that comes into direct contact with the corresponding terminal of the lithium ion secondary battery and has an area of 35 mm². The front end of each control probe (which includes the current supply probe pin and the voltage detection probe pin) was subjected to cutting such that grooves were formed in a grid pattern. Each voltage detection probe pin having a plastic insulator wound around its outer periphery was inserted into the corresponding current supply probe pin. The number of control probes prepared in this manner is two. A bearing portion prepared in the comparative example is a long stainless plate including through holes disposed to face the positive and negative terminals of the lithium ion secondary battery. A control probe unit in the comparative example was prepared by inserting the control probes into the through holes and fixing the control probes such that the control probes were non-rotatable. Similarly to the sample probes, pressing members included in the control probes are springs.

In the comparative example, no oxide film was removed. The comparative example involved carrying out measurements similarly to the practical example.

### Results of Charging and Discharging Test

Table 1 shows contact resistance between each probe and the corresponding terminal before and after the charging and discharging test. In the practical example where the oxide film removing mechanism is provided, the contact resistance is 0.098 mΩ before the charging and discharging test and is 0.108 mΩ after the charging and discharging test. In the comparative example where no oxide film removing mechanism is provided, the contact resistance is 0.154 mΩ before the charging and discharging test, which is higher than that in the practical example by 0.056 mΩ. In the comparative example, the contact resistance is 0.888 mΩ after the charging and discharging test, which is more significantly higher than that in the practical example.

TABLE 1
Table 1

| Contact Resistance [mΩ] | | Before Test | After Test |
|---|---|---|---|
| Oxide Film | Not Provided | 0.154 | 0.888 |
| Removing | (Comparative Example) | | |
| Mechanism | Provided | 0.098 | 0.108 |
| | (Practical Example) | | |

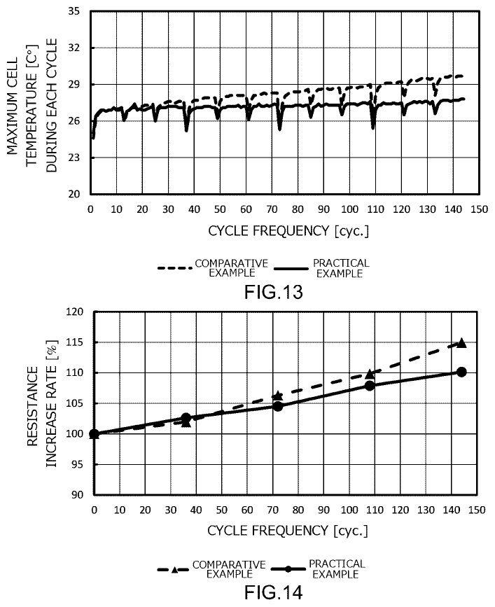

FIG. 12 is a graph illustrating changes in maximum terminal temperature during cycle test. FIG. 13 is a graph illustrating changes in maximum cell temperature in the lithium ion secondary battery during cycle test. The maximum terminal temperature is calculated by averaging the maximum temperature of the positive terminal and the maximum temperature of the negative terminal. FIG. 14 is a graph illustrating changes in increase rate of resistance of the lithium ion secondary battery during cycle test. In FIGS. 12 to 14, the broken lines indicate results obtained using the probes each including no oxide film removing mechanism, and the solid lines indicate results obtained using the probes each including the oxide film removing mechanism. In FIG. 12, the vertical axis represents the maximum terminal temperature) (C.° during each cycle, and the horizontal axis represents a cycle test frequency (i.e., the number of times the cycle test has been performed). In FIG. 13, the vertical axis represents the maximum cell temperature) (C.° of the lithium ion secondary battery during each cycle, and the horizontal axis represents a cycle frequency (i.e., the number of cycles performed). FIG. 14 presents measurements of the resistance increase rate (%) in the 0th cycle (at the start of the test), the 36th cycle, the 72th cycle, the 108th cycle, and the 144th cycle (at the end of the test). In FIG. 14, the horizontal axis represents the cycle frequency (i.e., the number of cycles performed), and the vertical axis represents the resistance increase rate during each cycle.

As illustrated in FIG. 12, in the comparative example where each probe is provided with no oxide film removing mechanism, a rise in terminal temperature tends to be larger as the cycle test frequency increases. As illustrated in FIG. 13, the maximum cell temperature increases as the cycle frequency increases. In such a case, electrolyte nonuniformity is considered to exist in the lithium ion secondary battery. This electrolyte nonuniformity may adversely affect battery performance. In the practical example where each probe is provided with the oxide film removing mechanism, if the cycle frequency increases, the terminal temperature is constant or substantially constant as illustrated in FIG. 12 and the cell temperature is constant or substantially constant as illustrated in FIG. 13. As illustrated in FIG. 14, in the practical example, a rise in contact resistance between each probe and the corresponding terminal is smaller than that in the comparative example.

What is claimed is:

1. A probe comprising:
an electrically conductive probe pin;
a pressing member to press the probe pin against a test object; and
a bearing portion holding the probe pin such that the probe pin is rotatable around an axis extending in a longitudinal direction of the probe pin, wherein
a front end of the probe pin includes
a flat contact portion that comes into direct contact with the test object, and
a groove extending from a center of the front end toward its outer periphery.

2. The probe according to claim 1, wherein
a contact area between the flat contact portion and the test object is at least 0.5 mm² or more,
the front end of the probe pin includes flat contact surfaces defined by the groove, and
the front end of the probe pin comes into contact with the test object through the contact surfaces.

3. The probe according to claim 1, wherein
a disengagement stopper to prevent disengagement of the probe pin is disposed adjacent to a rear end of the probe pin,
a projection projecting along an outer circumference of the probe pin is disposed adjacent to the front end of the probe pin,
the pressing member is disposed between the bearing portion and the projection, and
the pressing member presses the probe pin against the test object with a repulsive force.

4. The probe according to claim 1, wherein
the probe pin includes
a current supply probe pin to supply an electric current,
a voltage detection probe pin to detect a voltage, and
an insulator insulating the current supply probe pin and the voltage detection probe pin from each other.

5. The probe according to claim 4, wherein
the current supply probe pin has a cylindrical shape, and
the voltage detection probe pin is disposed inside the current supply probe pin, with the insulator interposed therebetween.

6. A probe unit to be connected to an electricity storage device, the probe unit comprising:
a first probe to be connected to a first electrode; and
a second probe to be connected to a second electrode, wherein
the first probe includes
a first probe pin that is electrically conductive,
a first probe pressing member to press the first probe against the first electrode, and
a first probe bearing portion holding the first probe pin such that the first probe pin is rotatable around an axis extending in a longitudinal direction of the first probe pin,
the second probe includes
a second probe pin that is electrically conductive,
a second probe pressing member to press the second probe against the second electrode, and
a second probe bearing portion holding the second probe pin such that the second probe pin is rotatable around an axis extending in a longitudinal direction of the second probe pin,
a front end of the first probe pin includes
a flat contact portion that comes into direct contact with the first electrode, and
a groove extending from a center of the front end of the first probe pin toward its outer periphery, and
a front end of the second probe pin includes
a flat contact portion that comes into direct contact with the second electrode, and
a groove extending from a center of the front end of the second probe pin toward its outer periphery.

7. An electricity storage device testing apparatus comprising:
the probe unit according to claim 6;
a holding plate to hold the electricity storage device and the probe unit;
a current generation section to supply an electric current or electric signal to the electricity storage device through the first probe and/or the second probe; and
a measurement section to measure an electric characteristic of the electricity storage device based on an electric signal received from the electricity storage device.

8. A testing method for testing an electric characteristic of a test object by bringing a front end of a probe into contact with the test object, the method comprising:
a contact step of bringing the front end of the probe into contact with a terminal of the test object;
a pressing and rotating step of rotating the front end of the probe while pressing the front end that is in contact with the terminal;
a supplying step of supplying an electric current or electric signal to the test object; and
a measuring step of measuring the electric characteristic of the test object based on an electric signal received from the test object.

9. The testing method according to claim 8, wherein
the supplying step involves passage of a constant current of at least 20 A or more.

10. The testing method according to claim 8, wherein
the testing object is an electricity storage device.
